(19) United States
(12) Patent Application Publication
(10) Pub. No.: US 2015/0059910 A1
(43) Pub. Date: Mar. 5, 2015

(54) PLASMA CVD APPARATUS, METHOD FOR FORMING FILM AND DLC-COATED PIPE

(71) Applicant: YOUTEC CO., LTD., Chiba (JP)

(72) Inventors: Yuuji HONDA, Chiba (JP); Norio ARAMAKI, Chiba (JP)

(21) Appl. No.: 14/466,186

(22) Filed: Aug. 22, 2014

(30) Foreign Application Priority Data
Aug. 27, 2013 (JP) 2013-175578

(51) Int. Cl. H01J 37/32; C23C 16/27; F16L 9/133; C23C 16/44

(52) U.S. Cl. CPC H01J 37/32394; C23C 16/4409; C23C 16/27; C23C 16/4404; H01J 37/32513; H01J 37/32577; H01J 37/32449; F16L 9/133; H01J 2237/1825; H01J 2237/3321
USPC 138/146; 118/723 R; 427/569

(57) ABSTRACT

To provide a plasma CVD apparatus capable of forming a thin film on the inner surface of a pipe even without a vacuum vessel. An aspect of the present invention is a plasma CVD apparatus including a first member sealing an end of a pipe; a second member sealing the other end of the pipe; a gas introduction mechanism that is connected to the first member and that introduces a raw material gas into the pipe; an exhausting mechanism that is connected to the second member and that vacuum-exhausts the inside of the pipe; an electrode disposed in the pipe; and a high-frequency power.

### BACKGROUND OF THE INVENTION

1. Field of the Invention

The present invention relates to a plasma CVD apparatus, a method for forming a film and a DLC-coated pipe.

2. Description of a Related Art

There will be explained a method for coating a Diamond Like Carbon (DLC) film on an outer peripheral surface of an insulating pipe by a conventional plasma CVD apparatus.

An insulating pipe is introduced into a vacuum vessel, an electrode is inserted into the hollow part of the pipe, the vacuum vessel is put into a reduced pressure state, a hydrocarbon gas is supplied to the outer peripheral surface of the pipe by introduction of the hydrocarbon gas into the vacuum vessel, plasma is generated at the outer peripheral surface of the pipe by application of a voltage to the electrode, and thus a DLC film is coated on the outer peripheral surface of the pipe (for example, see Patent Literature 1).

In the plasma CVD apparatus, a thin film is formed on the pipe in the vacuum vessel, and thus, when a large pipe is selected, it is necessary to make the vacuum vessel large in accordance with the pipe. For example, when a thin film is to be formed on the inner surface of such a large pipe as transporting fuel gas (for example, methane hydrate), a very large vacuum vessel is required to thereby raise the manufacturing cost of the apparatus. Furthermore, when the work of forming a thin film on the inner surface of the pipe is carried out in a factory, it is necessary to transport the large pipe to the factory and, after forming a film on the inner surface of the pipe, to transport the pipe to a place where the pipe is to be installed. Therefore, the transportation cost is high.
[Patent Literature 1]: Japanese Patent Laid-Open No. 2012-211349

### SUMMARY OF THE INVENTION

An aspect of the present invention is to provide a plasma CVD apparatus or a method for forming a film, capable of forming a thin film on the inner surface of a pipe, even without a vacuum vessel.

Furthermore, an aspect of the present invention is to provide a DLC-coated pipe in which a DLC film is formed on the inner surface of a pipe.

Hereinafter, various embodiments of the present invention will be explained.

[1] A plasma CVD apparatus, comprising:

a first sealing member sealing an end of a pipe;

a second sealing member sealing the other end of the pipe;

a gas introduction mechanism that is connected to the first sealing member and that introduces a raw material gas into the pipe;

an exhausting mechanism that is connected to the second sealing member and that vacuum-exhausts the inside of the pipe;

an electrode disposed in the pipe; and

a high-frequency power source electrically connected to the electrode or the pipe.

[2] The plasma CVD apparatus according to the above [1], wherein an earth is electrically connected to the pipe or the electrode.

[3] The plasma CVD apparatus according to the above [1] or [2], wherein the high-frequency power source has a frequency of 10 kHz to 1 MHz.

[4] The plasma CVD apparatus according to the above [1] or [2], wherein the high-frequency power source has a frequency of 50 kHz to 500 kHz.

[5] A plasma CVD apparatus, comprising:

a first sealing member sealing an end of a pipe;

a second sealing member sealing the other end of the pipe;

a gas introduction mechanism that is connected to the first sealing member and that introduces a raw material gas into the pipe;

an exhausting mechanism that is connected to the second sealing member and that vacuum-exhausts the inside of the pipe;

an electrode disposed in the pipe;

a first high-frequency power source that is electrically connected to the pipe and that has a frequency of 10 kHz to 1 MHz (preferably 50 kHz to 500 kHz);

a second high-frequency power source that is electrically connected to the pipe and that has a frequency of 2 MHz to 100 MHz; and

an earth electrically connected to the electrode.

[6] A plasma CVD apparatus, comprising:

a first sealing member sealing an end of a pipe;

a second sealing member sealing the other end of the pipe;

a gas introduction mechanism that is connected to the first sealing member and that introduces a raw material gas into the pipe;

an exhausting mechanism that is connected to the second sealing member and that vacuum-exhausts the inside of the pipe;

an electrode disposed in the pipe;

a first high-frequency power source that is electrically connected to the electrode and that has a frequency of 10 kHz to 1 MHz (preferably 50 kHz to 500 kHz);

a second high-frequency power source that is electrically connected to the electrode and that has a frequency of 2 MHz to 100 MHz; and

an earth electrically connected to the pipe.

(7) A plasma CVD apparatus, comprising:

a first sealing member sealing an end of a pipe;

a second sealing member sealing the other end of the pipe;

a gas introduction mechanism that is connected to the first sealing member and that introduces a raw material gas into the pipe;

an exhausting mechanism that is connected to the second sealing member and that vacuum-exhausts the inside of the pipe;

an electrode disposed in the pipe;

a first high-frequency power source that is electrically connected to the pipe and that has a frequency of 10 kHz to 1 MHz (preferably 50 kHz to 500 kHz); and

a second high-frequency power source that is electrically connected to the electrode and that has a frequency of 2 MHz to 100 MHz.

[8] A plasma CVD apparatus, comprising:

a first sealing member sealing an end of a pipe;

a second sealing member sealing the other end of the pipe;

a gas introduction mechanism that is connected to the first sealing member and that introduces a raw material gas into the pipe;

an exhausting mechanism that is connected to the second sealing member and that vacuum-exhausts the inside of the pipe;

an electrode disposed in the pipe;

a first high-frequency power source that is electrically connected to the electrode and that has a frequency of 10 kHz to 1 MHz (preferably 50 kHz to 500 kHz); and

a second high-frequency power source that is electrically connected to the pipe and that has a frequency of 2 MHz to 100 MHz.

[9] The plasma CVD apparatus according to any one of the above [1] to [8], wherein each of the first sealing member and the second sealing member has a vacuum sealing member to be contacted with an end part of the pipe.

[10] The plasma CVD apparatus according to the above [9], wherein each of the first sealing member and the second sealing member has an insulating member disposed in contact with the vacuum sealing member.

[11] The plasma CVD apparatus according to any one of the above [1] to [10], including a plurality of earth plates disposed in a vicinity of at least one of the first sealing member and the second sealing member and inside the pipe.

[12] The plasma CVD apparatus according to the above [11], wherein mutual distance between the plurality of earth plates is preferably 5 mm or less.

[13] The plasma CVD apparatus according to the above [11], wherein mutual distance between the plurality of earth plates is preferably 3 mm or less.

[14] The plasma CVD apparatus according to any one of the above [1] to [13], wherein the exhausting mechanism has a gas-gathering member gathering gas inside the pipe.

[15] A method for forming a film, comprising the steps of:

sealing both ends of a pipe;

introducing a raw material gas into the pipe; and

forming a film on an inner surface of the pipe by a plasma CVD method by supplying a high-frequency output to the inside of the pipe.

[16] The method for forming a film according to the above [15], wherein the high-frequency output has a frequency of 10 kHz to 1 MHz (preferably 50 kHz to 500 kHz).

[17] The method for forming a film according to the above [15], wherein both a high-frequency output having a frequency of 2 MHz to 100 MHz and a high-frequency output having a frequency of 10 kHz to 1 MHz (preferably 50 kHz to 500 kHz) are supplied to the inside of the pipe.

[18] A DLC-coated pipe, including:

a pipe; and

a DLC film formed on the inner surface of the pipe.

[19] The DLC-coated pipe according to the above [18], wherein the pipe is a metallic pipe, or a ceramics pipe, or a resin pipe.

According to an aspect of the present invention, there can be provided a plasma CVD apparatus or a method for forming a film, capable of forming a thin film on the inner surface of a pipe even without a vacuum vessel.

Furthermore, according to an aspect of the present invention, there can be provided a DLC-coated pipe with a DLC film formed on the inner surface of the pipe.

### BRIEF DESCRIPTION OF THE DRAWINGS

FIG. 1 is a cross-sectional view showing schematically the plasma CVD apparatus according to an aspect of the present invention.

FIG. 2 is a cross-sectional view showing schematically a modification 1 of the plasma CVD apparatus shown in FIG. 1.

FIG. 3 is a cross-sectional view showing schematically a modification 2 of the plasma CVD apparatus shown in FIG. 1.

FIG. 4 is a cross-sectional view showing schematically the plasma CVD apparatus according to an aspect of the present invention.

FIG. 5 is a cross-sectional view showing schematically a modification 1 of the plasma CVD apparatus shown in FIG. 4.

FIG. 6 is a cross-sectional view showing schematically a modification 2 of the plasma CVD apparatus shown in FIG. 4.

FIG. 7A is a photograph obtained by photographing the inner surface of a pipe before forming a DLC film, and FIG. 7B is a photograph obtained by photographing the inner surface of the pipe after forming a DLC film on the inner surface of the pipe.

### DESCRIPTION OF THE PREFERRED EMBODIMENTS

Hereinafter, embodiments of the present invention will be explained in detail using the drawings. However, a person skilled in the art would easily understand that the present invention is not limited to the explanation below, but that modes and details thereof can be changed in various ways without departing from the purport and the scope of the present invention. Accordingly, the present invention should not be construed as being limited to the description of the present embodiments shown below.

### First Embodiment

<Plasma CVD Apparatus>

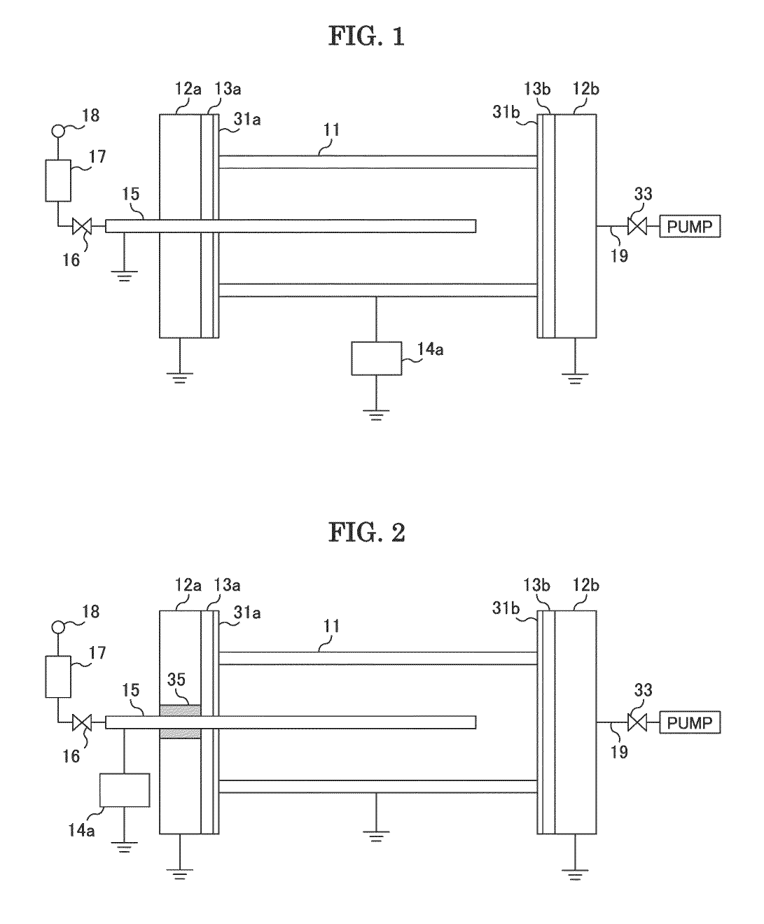

FIG. 1 is a cross-sectional view showing schematically the plasma CVD apparatus according to an aspect of the present invention.

The plasma CVD apparatus is an apparatus forming a thin film (for example a DLC film) on the inner surface of a pipe 11. The pipe 11 is, for example, a metallic pipe, a ceramics pipe, or a resin pipe.

The plasma CVD apparatus has a first sealing member sealing an end of the pipe 11, and a second sealing member sealing the other end of the pipe 11. The first sealing member has a first cover member 12a, an insulating member 13a is disposed on a surface of the first cover member 12a, and a first vacuum sealing member 31a is disposed in contact with a surface of the insulating member 13a. The second sealing member has a second cover member 12b, an insulating member 13b is disposed on a surface of the second cover member 12b, and a second vacuum sealing member 31b is disposed on a surface of the insulating member 13b.

The first cover member 12a covers an end of the pipe 11, and the second cover member 12b covers the other end of the pipe 11. The first vacuum sealing member 31a makes contact with the end part of the pipe 11 when an end of the pipe 11 is sealed with the first sealing member, and maintains the airtightness between the pipe 11 and the first cover member 12a. The insulating member 13a insulates reliably the first cover member 12a from the pipe 11. The second vacuum sealing member 31b makes contact with the end part of the pipe 11 when an end of the pipe 11 is sealed with the second sealing member, and maintains the airtightness between the pipe 11 and the second cover member 12b. The insulating member 13b insulates reliably the second cover member 12b from the pipe 11. Each of the first and second vacuum sealing members 31a, 31b is a plate formed of, for example, an elastic material (for example rubber). Even when the plate becomes thinner, the insulating members 13a and 13b can insulate reliably each of the first and second cover members 12a and 12b from the pipe 11, to thereby be able to suppress the generation of abnormal discharge.

A gas introduction mechanism introducing a raw material gas into the pipe 11 is connected to the first sealing member. The gas introduction mechanism has a nozzle 15, a vacuum valve 16, a mass flow controller 17 and a raw material gas generation source 18.

The nozzle 15 passes through the first cover member 12a, the insulating member 13a and the first vacuum sealing member 31a, and airtightness is maintained between each of the first cover member 12a, insulating member 13a and first vacuum sealing member 31a, and the nozzle 15.

It is configured such that the tip of the nozzle 15 is positioned inside the pipe 11, and that the base end of the nozzle 15 is positioned outside the pipe 11. The base end of the nozzle 15 is connected to one end side of the mass flow controller 17 via the vacuum valve 16, and the other end side of the mass flow controller 17 is connected to the raw material gas generation source 18 via a vacuum valve or the like, not shown. The raw material gas generation source 18 generates different kinds of raw material gases depending on a thin film to be formed on the inner surface of the pipe 11, and when a DLC film is to be formed, a gas containing, for example, carbon and hydrogen may be used. Furthermore, a plurality of holes (not shown) for blowing off the raw material gas is provided on the tip side of the nozzle 15 lying inside the pipe 11.

To the second sealing member, an exhausting mechanism (not shown) vacuum-exhausting the inside of the pipe 11 is connected. The exhausting mechanism has a through-hole (not shown) passing through the second cover member 12b, the insulating member 13b and the second vacuum sealing member 31b, and the through-hole is connected to a vacuum pump (PUMP). Thus, the gas inside the pipe 11 is exhausted by the vacuum pump (PUMP) through an exhaust channel 19 and a vacuum valve 33 to the outside of the pipe.

The nozzle 15 functions also as an electrode, and is electrically connected to the earth. Further, each of the first cover member 12a and the second cover member 12b is electrically connected to the earth.

To the pipe 11, a high-frequency power source 14a is electrically connected, and the high-frequency power source 14a is electrically connected to the earth. The frequency of the high-frequency power source may exceed 1 MHz, but preferably is 10 kHz to 1 MHz, more preferably 50 kHz to 500 kHz.

<Method for Forming a Film>

A method for forming a thin film on the inner surface of the pipe 11 using the plasma CVD apparatus shown in FIG. 1 will be explained.

First, both ends of the pipe 11 are sealed by pushing the first vacuum sealing member 31a against an end of the pipe 11 to cover the end of the pipe 11 with the first cover member 12a and pushing the second vacuum sealing member 31b against the other end of the pipe 11 to cover the other end of the pipe 11 with the second cover member 12b. Further, to the pipe 11, the high-frequency power source 14a is electrically connected. Thus, the plasma CVD apparatus shown in FIG. 1 is installed on the pipe 11.

Next, a raw material gas (for example toluene (C₇H₈)) is generated in the raw material gas generation source 18, the raw material gas is controlled to a prescribed flow rate by the mass flow controller 17, and the raw material gas is blown off from the plurality of holes of the nozzle 15 into the pipe 11. Then the inside of the pipe 11 is kept at a pressure suitable for forming a film by a CVD method, by the balance between the flow rate of the raw material gas thus controlled and the exhaust capacity of the exhausting mechanism.

Next, a high-frequency output of 10 kHz to 1 MHz (preferably 50 kHz to 500 kHz) is supplied from the high-frequency power source 14a to the pipe 11. At this time, the nozzle 15 is connected to the earth. Consequently, plasma is ignited between the pipe 11 and the nozzle 15, and plasma is generated inside the pipe 11 to form a thin film (for example, a DLC film) on the inner surface of the pipe 11.

According to the first embodiment, a thin film can be formed on the inner surface of the pipe 11, even without a vacuum vessel used in conventional technology. Therefore, even when the pipe 11 is large, a large vacuum vessel in accordance with the pipe is unnecessary, and the manufacturing cost of a plasma CVD apparatus can be suppressed to be low. Further, since a work for forming a thin film on the inner surface of the pipe 11 can be carried out in a site where the pipe is to be installed, the cost can be reduced as compared with the case where the film forming operation is carried out in a factory.

Further, in the embodiment, since an RF plasma having a frequency of 10 kHz to 1 MHz is used, induction heating is hardly generated in the pipe 11, and since a sufficient V_{DC} is supplied to the inner surface of the pipe 11 in the film forming, a thin film with high hardness can be formed.

Meanwhile, in the embodiment, the high-frequency power source 14a having a single frequency is electrically connected to the pipe 11 to thereby supply a high-frequency power of a single frequency to the pipe 11. However, the embodiment is not limited to the case, and both a first high-frequency power source having a frequency of 10 kHz to 1 MHz (preferably 50 kHz to 500 kHz) and a second high-frequency power source having a frequency of 2 MHz to 100 MHz may be electrically connected to the pipe 11 to thereby supply simultaneously a high-frequency power having a frequency of 10 kHz to 1 MHz (preferably 50 kHz to 500 kHz) and a high-frequency power having a frequency of 2 MHz to 100 MHz to the pipe 11.

### Modification 1

FIG. 2 is a cross-sectional view showing schematically a modification 1 of the plasma CVD apparatus shown in FIG. 1, in which the same sign is attached to the same part as in FIG. 1 and only different parts will be explained.

The earth is electrically connected to the pipe 11, and the high-frequency power source 14a is electrically connected to the nozzle 15. The nozzle 15 and the first con member 12a are insulated from each other by the insulating member 35.

Also in the modification, the same effect as that in the first embodiment can be obtained.

Meanwhile, in the modification, the high-frequency power source 14a having a single frequency is electrically connected to the nozzle 15 to thereby supply a high-frequency power of a single frequency to the nozzle 15. However, the modification is not limited to the case, and both the first high-frequency power source having a frequency of 10 kHz to 1 MHz (preferably 50 kHz to 500 kHz) and the second high-frequency power source having a frequency of 2 MHz to 100 MHz may be electrically connected to the nozzle 15 to thereby supply simultaneously a high-frequency power having a frequency of 10 kHz to 1 MHz (preferably 50 kHz to 500 kHz) and a high-frequency power having a frequency of 2 MHz to 100 MHz to the nozzle 15.

### Modification 2

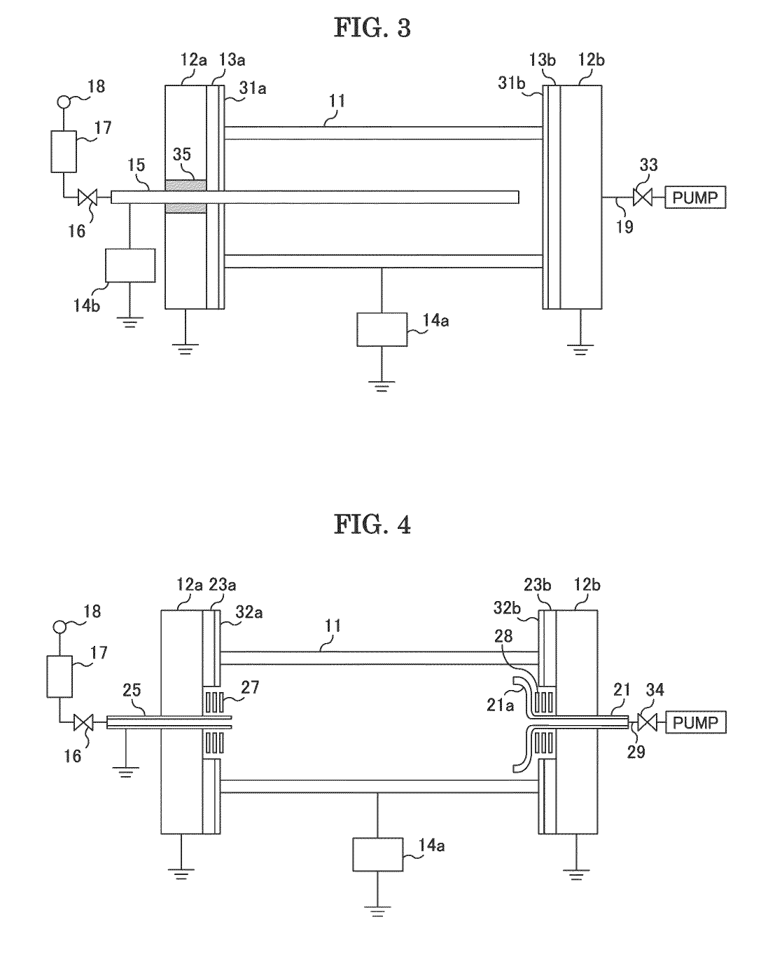

FIG. 3 is a cross-sectional view showing schematically a modification 2 of the plasma CVD apparatus shown in FIG. 1, in which the same sign is attached to the same part as in FIG. 1 and only different parts will be explained.

The high-frequency power source 14a having a frequency of 10 kHz to 1 MHz (preferably 50 kHz to 500 kHz) is electrically connected to the pipe 11, and the high-frequency power source 14b having a frequency of 2 MHz to 100 MH is electrically connected to the nozzle 15. The nozzle 15 and the first cover member 12a are insulated from each other by the insulating member 35.

Also in the modification, the same effect as that in the first embodiment can be obtained.

Meanwhile, in the modification, the high-frequency power source 14a is electrically connected to the pipe 11 and the high-frequency power source 14b is electrically connected to the nozzle 15. However, the high-frequency power source 14a may be electrically connected to the nozzle and the high-frequency power source 14b may be electrically connected to the pipe 11.

### Second Embodiment

<Plasma CVD Apparatus>

FIG. 4 is a cross-sectional view showing schematically the plasma CVD apparatus according to an aspect of the present invention, in which the same sign is attached to the same portion as in FIG. 1 and only different portions will be explained.

The gas introduction mechanism has a nozzle 25, the vacuum valve 16, the mass flow controller 17 and the raw material gas generation source 18. The nozzle 25 has a length extending in the pipe 11 shorter than that of the nozzle 15 in the first embodiment. A plurality of openings (not shown) for blowing off the raw material gas is provided on the tip side of the nozzle 25 positioned inside the pipe 11.

An exhausting mechanism vacuum-exhausting the inside of the pipe 11 is connected to the second sealing member. The exhausting mechanism has an exhaust channel 21, 29 passing through the second cover member 12b, and an end of the exhaust channel 21, 29 is connected to a vacuum pump (PUMP). The other end of the exhaust channel 21, 29 has a gas-gathering member 21a gathering the gas inside the pipe 11. The gas-gathering member 21a has a shape having a concave face that opens from the center of the pipe 11 toward the inside surface side thereof. Hereby, the raw material gas blown off from the tip side of the nozzle 25 is gathered by the gas-gathering member 21a and the gathered raw material gas passes through the exhaust channel 21, 29 and the vacuum valve 34 to be exhausted to the outside of the pipe 11.

In the vicinity of the nozzle 25, the first cover member 12a, the insulating member 23a and the first vacuum sealing member 32a, a plurality of earth plates 27 electrically connected to the earth are disposed. That is, the plurality of earth plates 27 is disposed in the vicinity of the first sealing member and inside the pipe 11. Hereby, discharge can be carried out between the plurality of earth plates 27 and the inner surface of the pipe 11.

In the vicinity of the gas-gathering member 21a, the exhaust channel 21, 29, the second cover member 12b, the insulating member 23b and the second vacuum sealing member 32b, a plurality of earth plates 28 electrically connected to the earth are disposed. That is, the plurality of earth plates 28 is disposed in the vicinity of the second sealing member and inside the pipe 11. Discharge can be carried out between the plurality of earth plates 28 and the inner surface of the pipe 11.

In the case where the apparatus is operated for a long period of time to thereby form a CVD film of an insulating body on the surface of the nozzle 25, and as a result, the discharge stops to be generated between the nozzle 25 and the pipe 11, the plurality of earth plates 27 and 28 work as an opposite electrode in place of the nozzle 25 to make it possible to generate discharge between the plurality of earth plates 27 and 28 and the inner surface of the pipe 11. Accordingly, the provision of the plurality of earth plates 27 and 28 makes it possible to operate continuously the apparatus for a long period of time.

The mutual distance between the plurality of earth plates 27 and 28 is preferably 5 mm or less (more preferably 3 mm or less). Hereby, the formation of the CVD film in the gap between mutual plates in the plurality of earth plates 27 and 28 can be suppressed. As a result, the apparatus can be operated continuously for a longer period of time.

<Method for Forming Film>

The method for forming a thin film on the inner surface of the pipe 11 using the plasma CVD apparatus shown in FIG. 4 is the same as that in the first embodiment.

Also in the embodiment, the same effect as that in the first embodiment can be obtained.

Meanwhile, in the embodiment, the high-frequency power source 14a having a single frequency is electrically connected to the pipe 11 to thereby supply a high-frequency power of a single frequency to the pipe 11. However, the embodiment is not limited to the case, and both the first high-frequency power source having a frequency of 10 kHz to MHz (preferably 50 kHz to 500 kHz) and the second high-frequency power source having a frequency of 2 MHz to 100 MHz may be electrically connected to the pipe 11 to thereby supply simultaneously a high-frequency power having a frequency of 10 kHz to 1 MHz (preferably 50 kHz to 500 kHz) and a high-frequency power having a frequency of 2 MHz to 100 MHz to the pipe 11.

### Modification 1

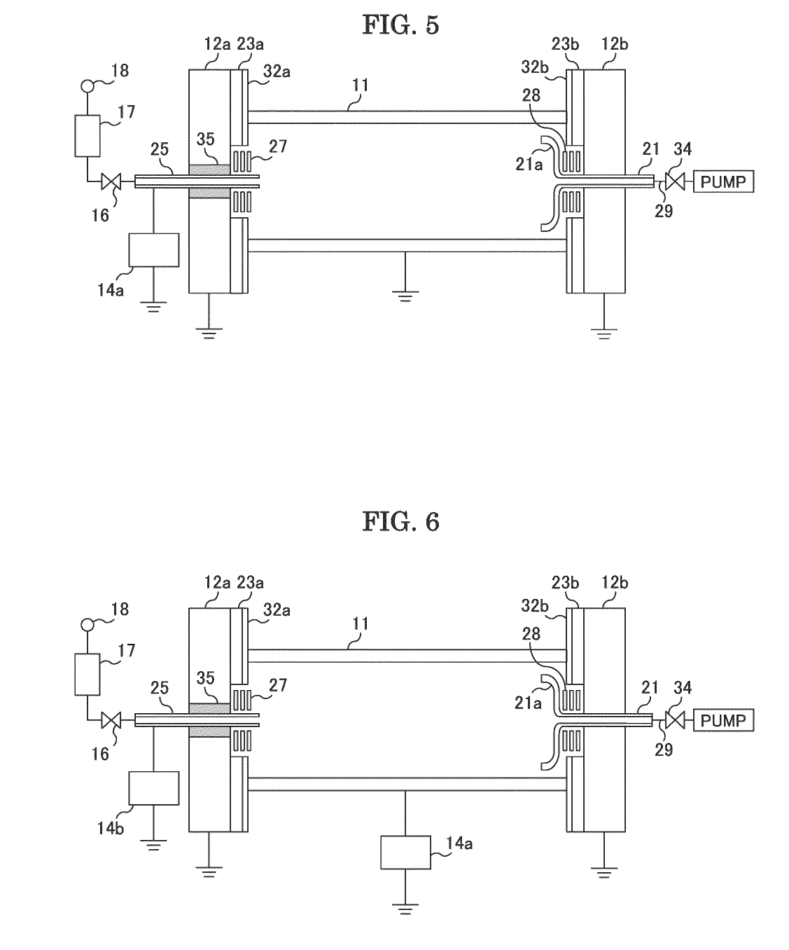

FIG. 5 is a cross-sectional view showing schematically a modification 1 of the plasma CVD apparatus shown in FIG. 4, in which the same sign is attached to the same part as in FIG. 4 and only different parts will be explained.

The earth is electrically connected to the pipe 11, and the high-frequency power source 14a is electrically connected to the nozzle 25. The nozzle 25 and the first con member 12a are insulated from each other by the insulating member 35.

Also in the modification, the same effect as that in the second embodiment can be obtained.

Meanwhile, in the modification, the high-frequency power source 14a having a single frequency is electrically connected to the nozzle 25 to thereby supply a high-frequency power of a single frequency to the nozzle 25. However, the example is not limited to the case, and both the first high-frequency power source having a frequency of 10 kHz to 1 MHz (preferably 50 kHz to 500 kHz) and the second high-frequency power source having a frequency of 2 MHz to 100 MHz may be electrically connected to the nozzle 25 to thereby supply simultaneously a high-frequency power having a frequency of 10 kHz to 1 MHz (preferably 50 kHz to 500 kHz) and a high-frequency power having a frequency of 2 MHz to 100 MHz to the nozzle 25.

### Modification 2

FIG. 6 is a cross-sectional view showing schematically a modification 2 of the plasma CVD apparatus shown in FIG. 4, in which the same sign is attached to the same part as in FIG. 4 and only different parts will be explained.

The high-frequency power source 14a having a frequency of 10 kHz to 1 MHz (preferably 50 kHz to 500 kHz) is electrically connected to the pipe 11, and the high-frequency power source 14b having a frequency of 2 MHz to 100 MHz is electrically connected to the nozzle 25. The nozzle 25 and the first cover member 12a are insulated from each other by the insulating member 35.

Also in the modification, the same effect as that in the second embodiment can be obtained.

Meanwhile, in the modification, the high-frequency power source 14a is electrically connected to the pipe 11 and the high-frequency power source 14b is electrically connected to the nozzle 25. However, the high-frequency power source 14a may be electrically connected to the nozzle and the high-frequency power source 14b may be electrically connected to the pipe 11.

### Example

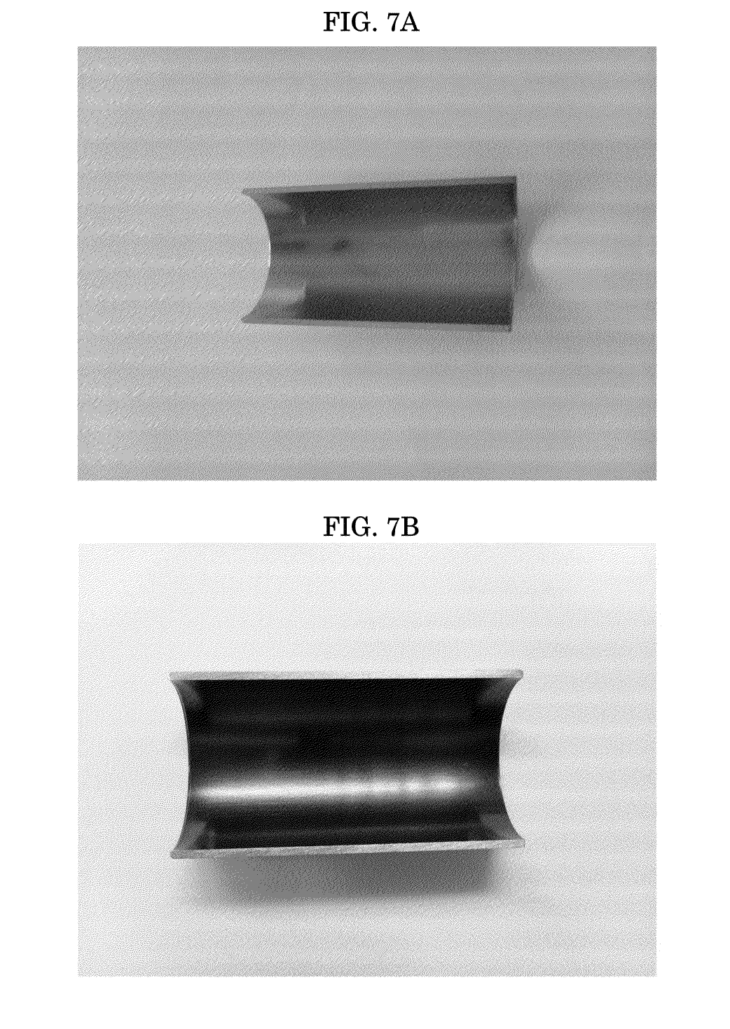

FIG. 7A is a photograph obtained by photographing the inner surface of a pipe before forming a DLC film. FIG. 7B is a photograph obtained by photographing the inner surface of the pipe after forming a DLC film on the inner surface of the pipe.

As shown in FIG. 7B, it was confirmed that a DLC film could be formed on the inner surface of the pipe.

### DESCRIPTION OF REFERENCE SYMBOLS

1 pipe
12a first cover member
12b second cover member
13a and 13b insulating member
14a and 14b high-frequency power source
15 nozzle
16 vacuum valve
17 mass flow controller
18 raw material gas generation source
19 and 21 exhaust channel
21a gas-gathering member
23a and 23b insulating member
25 nozzle
27 and 28 plurality of earth plates
29 exhaust channel
31a first vacuum sealing member
31b second vacuum sealing member
32a first vacuum sealing member
32b second vacuum sealing member
33 and 34 vacuum valve
35 insulating member

1. A plasma CVD apparatus comprising:
a first member sealing an end of a pipe;
a second member sealing the other end of the pipe;
a gas introduction mechanism that is connected to the first member and that introduces a raw material gas into the pipe;
an exhausting mechanism that is connected to the second member and that vacuum-exhausts the inside of the pipe;
an electrode disposed in the pipe; and
a high-frequency power source electrically connected to the electrode or the pipe.

2. The plasma CVD apparatus according to claim 1, wherein an earth is electrically connected to the pipe or the electrode.

3. The plasma CVD apparatus according to claim 1, wherein the high-frequency power source has a frequency of 10 kHz to 1 MHz.

4. The plasma CVD apparatus according to claim 1, wherein the high-frequency power source has a frequency of 50 kHz to 500 kHz.

5. A plasma CVD apparatus, comprising:
a first member sealing an end of a pipe;
a second member sealing the other end of the pipe;
a gas introduction mechanism that is connected to the first member and that introduces a raw material gas into the pipe;
an exhausting mechanism that is connected to the second member and that vacuum-exhausts the inside of the pipe;
an electrode disposed in the pipe;
a first high-frequency power source that is electrically connected to the pipe and that has a frequency of 10 kHz to 1 MHz;
a second high-frequency power source that is electrically connected to the pipe and that has a frequency of 2 MHz to 100 MHz; and
an earth electrically connected to the electrode.

6. A plasma CVD apparatus, comprising:
a first member sealing an end of a pipe;
a second member sealing the other end of the pipe;
a gas introduction mechanism that is connected to the first member and that introduces a raw material gas into the pipe;
an exhausting mechanism that is connected to the second member and that vacuum-exhausts the inside of the pipe;
an electrode disposed in the pipe;
a first high-frequency power source that is electrically connected to the electrode and that has a frequency of 10 kHz to 1 MHz;
a second high-frequency power source that is electrically connected to the electrode and that has a frequency of 2 MHz to 100 MHz; and
an earth electrically connected to the pipe.

7. A plasma CVD apparatus, comprising:
a first member sealing an end of a pipe;
a second member sealing the other end of the pipe;
a gas introduction mechanism that is connected to the first member and that introduces a raw material gas into the pipe;
an exhausting mechanism that is connected to the second member and that vacuum-exhausts the inside of the pipe;
an electrode disposed in the pipe;
a first high-frequency power source that is electrically connected to the pipe and that has a frequency of 10 kHz to 1 MHz; and
a second high-frequency power source that is electrically connected to the electrode and that has a frequency of 2 MHz to 100 MHz.

8. A plasma CVD apparatus, comprising:
a first member sealing an end of a pipe;
a second member sealing the other end of the pipe;
a gas introduction mechanism that is connected to the first member and that introduces a raw material gas into the pipe;
an exhausting mechanism that is connected to the second member and that vacuum-exhausts the inside of the pipe;
an electrode disposed in the pipe;
a first high-frequency power source that is electrically connected to the electrode and that has a frequency of 10 kHz to 1 MHz; and
a second high-frequency power source that is electrically connected to the pipe and that has a frequency of 2 MHz to 100 MHz.

9. The plasma CVD apparatus according to claim 1, wherein each of the first member and the second member has a vacuum sealing member to be contacted with an end part of the pipe.

10. The plasma CVD apparatus according to claim 5, wherein each of the first member and the second member has a vacuum sealing member to be contacted with an end part of the pipe.

11. The plasma CVD apparatus according to claim 9, wherein each of the first member and the second member has an insulating member disposed in contact with the vacuum sealing member.

12. The plasma CVD apparatus according to claim 1, including a plurality of earth plates disposed in a vicinity of at least one of the first member and the second member and inside the pipe.

13. The plasma CVD apparatus according to claim 5, including a plurality of earth plates disposed in a vicinity of at least one of the first member and the second member and inside the pipe.

14. The plasma CVD apparatus according to claim 12, wherein mutual distance between the plurality of earth plates is preferably 5 mm or less.

15. The plasma CVD apparatus according to claim 12, wherein mutual distance between the plurality of earth plates is preferably 3 mm or less.

16. The plasma CVD apparatus according to claim 5, wherein the exhausting mechanism has a gas-gathering member gathering gas inside the pipe.

17. A method for forming a film, comprising the steps of:
sealing both ends of a pipe;
introducing a raw material gas into the pipe; and
forming a film on an inner surface of the pipe by a plasma CVD method by supplying a high-frequency output to the inside of the pipe.

18. The method for forming a film according to claim 17, wherein the high-frequency output has a frequency of 10 kHz to 1 MHz.

19. The method for forming a film according to claim 17, wherein both a high-frequency output having a frequency of 2 MHz to 100 MHz and a high-frequency output having a frequency of 10 kHz to 1 MHz are supplied to the inside of the pipe.

20. A DLC-coated pipe, comprising:
a pipe; and
a DLC film formed on the inner surface of the pipe.

21. The DLC-coated pipe according to claim 20, wherein the pipe is a metallic pipe, or a ceramics pipe, or a resin pipe.
